(19) United States
(12) Patent Application Publication
(10) Pub. No.: US 2010/0154881 A1
(43) Pub. Date: Jun. 24, 2010

(54) TRANSPARENT SOLAR CELL MODULE AND METHOD OF FABRICATING THE SAME

(75) Inventors: Chian-Fu Huang, Keelung City (TW); Chao-Hsien Kuo, Hsinchu City (TW); Hsuan-Yin Fang, Taichung City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/389,385

(22) Filed: Feb. 20, 2009

(30) Foreign Application Priority Data
Dec. 23, 2008 (TW) 97150315

(51) Int. Cl. H01L 31/00; H01L 21/02

(52) U.S. Cl. 136/256; 438/29; 257/E21.002

(57) ABSTRACT

A transparent solar cell module is provided. The transparent solar cell module includes a transparent substrate, a first transparent electrode on the transparent substrate, a p-type layer on the first transparent electrode, an intrinsic layer on the p-type layer, an n-type stacked layer on the intrinsic layer, and a second transparent electrode on the n-type stacked layer. The n-type stacked layer includes at least two n-type material layers with different refractive indexes.

### CROSS-REFERENCE TO RELATED APPLICATION

This application claims the priority benefit of Taiwan application serial no. 97150315, filed on Dec. 23, 2008. The entirety of the above-mentioned patent application is hereby incorporated by reference herein and made a part of specification.

### BACKGROUND OF THE INVENTION

1. Field of the Invention

The present invention generally relates to a cell module and a method of fabricating the same, in particular, to a transparent solar cell module and a method of fabricating the same.

2. Description of Related Art

Solar energy is an inexhaustible and pollution-free energy source. In solving the pollution and shortage of current petrochemical energy source, the solar energy is the most important focus. The solar cell, capable of directly converting solar energy into electrical energy, is a very important research subject at present. Some patents have already disclosed related technologies on solar cells and methods of fabricating the same, for example, U.S. Pat. No. 4,623,601, U.S. Pat. No. 4,781,765, and U.S. Pat. No. 5,569,332.

An early solar cell is usually disposed on a roof. However, in an urban area having too many people with few lands, the roof area is quite limited, and only a small area is available for disposing solar cells. However, an area of glass curtain walls of building elevations is quite large and is not constrained by laws, and the area may be utilized by a solar cell module. Thus, a building integrated photovoltaic (BIPV) will be an important application and market for a whole silicon film solar cell. Among light transparent BIPV technologies applicable to elevations, one is a see-through type BIPV achieved by removing a partial of the device area, and another one is a transparent-type BIPV in which all the upper and lower electrodes are transparent electrodes.

However, as the partial device area has to be removed by a laser when fabricating a see-through type solar cell, its fabrication cost is high. In addition, the transparent parts and opaque parts are interlaced as a net, which makes people dizzy when watching closely. For the transparent solar cell, the silicon film mainly absorbs light at short wavelengths, which makes the transmission spectrum mainly at long wavelength, so that the light transmitted appears orange and deep red. Although, for application in glass curtains, an outside wall of a building may still be beautiful, the indoor color is changed, failing to conform to the demands. Therefore, keeping indoor color unchanged will be an important subject for the BIPV application on glass curtains in the future.

### SUMMARY OF THE INVENTION

The present invention is directed to a transparent solar cell module that may adjust the color code, the color rendering index, and the color temperature of a transmission spectrum.

The present invention is directed to a transparent solar cell module that may increase absorption of light at long wavelengths, and enhance a short-circuit current density Jsc and efficiency of devices.

The present invention is directed to a transparent solar cell module that may be applied to a building integrated photovoltaic (BIPV).

The present invention is further directed to a method of fabricating a transparent solar cell module, which conforms to the current fabricating process of solar cell, and has low fabrication cost.

The present invention provides a transparent solar cell module. The transparent solar cell module includes a transparent substrate, a first transparent electrode on the transparent substrate, a first conductive type layer on the first transparent electrode, an intrinsic layer on the first conductive type layer, a second conductive type stacked layer on the intrinsic layer, and a second transparent electrode on the second conductive type stacked layer. The second conductive type stacked layer includes at least two second conductive type material layers with different refractive indexes.

The present invention also provides a method of fabricating a transparent solar cell module. A first transparent electrode is formed on a transparent substrate. A first conductive type layer is formed on the first transparent electrode. An intrinsic layer is formed on the first conductive type layer. A second conductive type stacked layer is formed on the intrinsic layer. The second conductive type stacked layer includes at least two second conductive type material layers with different refractive indexes. Finally, a second transparent electrode is formed on the second conductive type stacked layer.

The transparent solar cell module of the present invention may adjust the color code, the color rendering index, and the color temperature of a transmission spectrum, so as to improve a quality of transmitted light, and achieve a more comfortable living space.

The transparent solar cell module of the present invention may increase absorption of light at long wavelengths, and increase a short-circuit current density Jsc and efficiency of devices, so as to achieve energy-saving.

The transparent solar cell module of the present invention may be applied to the BIPV.

The method of fabricating the transparent solar cell module of the present invention may conform to current manufacturing process technologies of solar cells, and have low manufacturing cost.

To clarify the foregoing and other objectives, features, and advantages of the present invention, a plurality of embodiments are illustrated in detail in association with the accompanying drawings in the following.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic sectional view of a transparent solar cell module according to an embodiment of the present invention.

FIG. 2 is a relationship diagram between light absorption quantum efficiency and wavelength for solar cell modules fabricated according to a method in an embodiment of the present invention and a conventional method.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

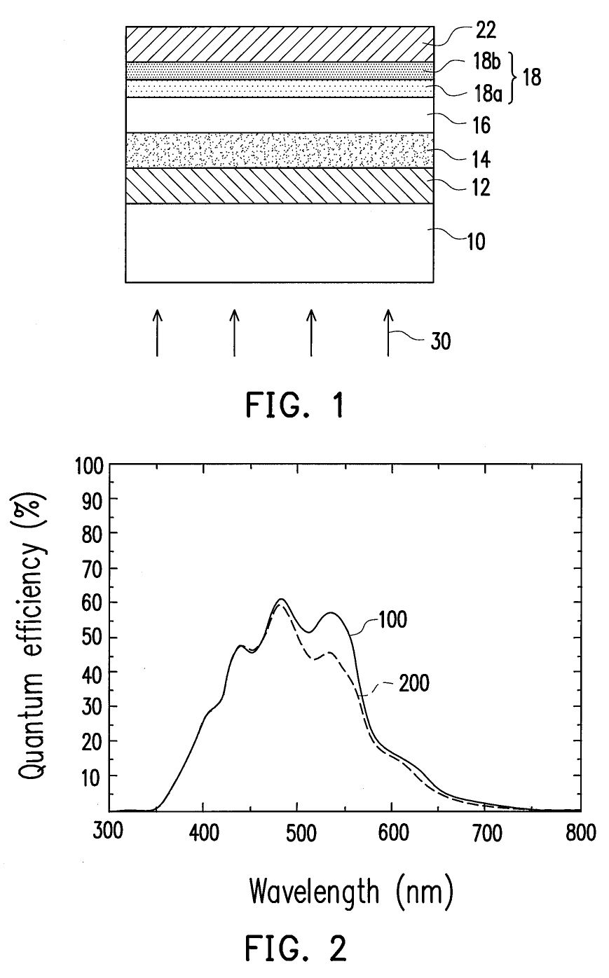

FIG. 1 is a schematic sectional view of a transparent solar cell module according to an embodiment of the present invention.

Referring to FIG. 1, the transparent solar cell module of the present invention includes a transparent substrate 10, a transparent electrode (a front electrode) 12, a first conductive type layer 14, an intrinsic layer (orI layer) 16, a second conductive type layer 18 (18a/18b), and a transparent electrode (a rear electrode) 22. In an embodiment, the first conductive type is p-type and the second conductive type is n-type. In another embodiment, the first conductive type is n-type and the second conductive type is p-type. The second conductive type layer 18 in the transparent solar cell module of the present invention includes at least two second conductive type material layers 18a and 18b with different refractive indexes. The second conductive type layer 18 can adjust the color code, the color rendering index, and the color temperature of a transmission spectrum, so that the transmitted color is close to a color of a natural light. Additionally, the n-type stacked layer of the present invention may serve as a reflective layer to increase a quantum efficiency (QE) of light absorption of light at wavelengths between 500 nm and 800 nm, so as to enhance a short-circuit current density Jsc and efficiency of devices. Hereinafter, the example with the first conductive type being p-type and the second conductive type being n-type is used to illustrate the transparent solar cell module of the present invention. However, the present invention is not limited to this example.

Referring to FIG. 1, the transparent solar cell module of the embodiment of the present invention includes the transparent substrate 10, the transparent electrode 12 on the transparent substrate 10, the p-type layer 14 on the transparent electrode 12, the intrinsic layer (I layer) 16 on the p-type layer 14, the n-type stacked layer 18 on the intrinsic layer 16, and the transparent electrode 22 on the n-type stacked layer 18. The n-type stacked layer 18 includes at least two n-type material layers 18a and 18b with different refractive indexes.

The transparent substrate 10 may be a rigid substrate or a flexible substrate. The rigid substrate is, for example, a curtain glass substrate for a building. The flexible substrate is, for example, a plastic substrate.

The transparent electrode 12 serves as a front electrode, the material of which is, for example, transparent conductive oxide (TCO), such as, indium tin oxide (ITO), fluorine-doped tin oxide (FTO), aluminium-doped zinc oxide (AZO), gallium-doped zinc oxide (GZO), or a combination thereof. A method of forming the transparent electrode 12 on the substrate 10 is, for example, chemical vapor deposition (CVD), physical vapor deposition (PVD), or a spraying process.

The p-type layer 14 is a semiconductor with a p-type dopant or a p-type insulation layer. The p-type dopant is, for example, boron. The semiconductor with the p-type dopant is, for example, p-type amorphous silicon, p-type microcrystalline silicon, p-type silicon carbide, or p-type silicon oxide. The p-type insulation layer is, for example, p-type silicon oxide. In an embodiment, the p-type layer 14 is p-type amorphous silicon, and its thickness is, for example, 5-10 nm. In another embodiment, the p-type layer 14 is p-type silicon oxide, and its thickness is, for example, 5-10 nm. For example, the p-type layer 14 is formed on the transparent electrode 12 by CVD after the transparent electrode 12 is formed on the substrate 10. The p-type dopant in the p-type layer 14 can be in-situ doped during the deposition process, or be formed by utilizing an ion implantation process after the deposition process is completed.

A material of the intrinsic layer 16 includes an intrinsic semiconductor, a doped intrinsic semiconductor, and the dopant is, for example, fluorine. The intrinsic layer 16 is, for example, intrinsic amorphous silicon, intrinsic microcrystalline silicon, fluorine-doped intrinsic amorphous silicon, or fluorine-doped intrinsic microcrystalline silicon. In an embodiment, the intrinsic layer 16 is intrinsic amorphous silicon, and its thickness is, for example, 90-100 nm. In another embodiment, the intrinsic layer 16 is fluorine-doped amorphous silicon, and its thickness is, for example, less than 100 nm. For example, the intrinsic layer 16 is formed on the p-type layer 14 by CVD after the p-type layer 14 is formed on the transparent electrode 12.

The n-type stacked layer 18 includes at least two n-type material layers 18a and 18b with different refractive indexes. The n-type material layer refers to that, for example, nitrogen, phosphorus, or arsenic exists in the material layer. In other words, the n-type stacked layer 18 includes at least one n-type material layer with a low refractive index and at least one n-type material layer with a high refractive index. A difference between the refractive index of the n-type material layer with the high refractive index and the refractive index of the n-type material layer with the low refractive index is, for example, greater than or equal to 1. In an embodiment, the refractive index of the n-type material layer with the low refractive index is, for example, 2-2.5. The refractive index of the n-type material layer with the high refractive index is, for example, 3-4. A material of the n-type material layer with the high refractive index includes n-type amorphous silicon (N-a-Si) or n-type microcrystalline silicon (N-μc-Si). A material of the n-type material layer with the low refractive index includes n-type silicon oxide (N—SiOₓ), silicon nitride (SiNₓ), or n-type silicon carbide (N—SiCₓ). The X in N—SiOₓ, N—SiNₓ, and N—SiCₓ represents any possible ratio. In another embodiment, the material layer 18a is the n-type material layer with the low refractive index, and the material layer 18b is the n-type material layer with the high refractive index. The n-type material layer 18a with the low refractive index is disposed between the intrinsic layer 16 and the n-type material layer 18b with the high refractive index. The n-type material layer 18b with the high refractive index is disposed between the n-type material layer 18a with the low refractive index and the transparent electrode 22. In an embodiment, the n-type stacked layer 18 includes the material layer 18a with the low refractive index and the material layer 18b with the high refractive index. The material layer 18b with the high refractive index is N-a-Si, and its dark conductivity is greater than 1×10⁻⁴ S/cm, and its thickness is, for example, 200-300 Å. The material layer 18a with the low refractive index is N—SiOₓ, and its dark conductivity is greater than 1×10⁻⁶ S/cm, and its thickness is, for example, 400-800 Å. The material layers 18a and 18b in the n-type stacked layer 18 are formed, for example, sequentially by the CVD process after the intrinsic layer 16 is formed on the p-type layer 14.

The transparent electrode 22 serves as a rear electrode, a material of which may be different from or the same as that of the transparent electrode 12. The material of the transparent electrode 22 is, for example, TCO, such as, ITO, FTO, AZO, GZO, aluminium-doped lead oxide, or a combination thereof. The transparent electrode 22 is formed, for example, on the n-type stacked layer 18 by the CVD, the PVD, or the spraying process after the n-type stacked layer 18 is formed.

After a light beam 30 enters via the transparent substrate 10 and passes through the intrinsic layer 16, as the material layer 18a with the low refractive index in the n-type stacked layer 18 can reflect the light beam back to the intrinsic layer 16, and an amount of the optical gain that is reflected to the intrinsic layer 16 is utilized for re-absorption of light at wavelengths in the visible range by the intrinsic layer 16, so that more photocurrent may be generated. Additionally, as the two electrodes 12 and 22 have light transmissive effect by using transparent materials, the electrodes 12 and 22 may be applied to the building integrated photovoltaic (BIPV) so as to achieve integration into a building.

In the above embodiment, the transparent substrate, the transparent electrode (the front electrode), the p-type layer, the intrinsic layer (I layer), the n-type stacked layer, the transparent electrode (the rear electrode) are taken as examples to illustrate the solar cell module including the transparent substrate 10, the transparent electrode (the front electrode) 12, the first conductive type layer 14, the intrinsic layer (I layer) 16, the second conductive type layer 18 (18a/18b), and the transparent electrode (the rear electrode) 22 of the present invention. However, the present invention is not limited to this example. As long as the second conductive type layer in the solar cell module includes at least two second conductive type material layers with different refractive indexes, the solar cell module falls within the coverage of the present invention.

Additionally, the material, the number of the material layers, and the configuration manner of the second conductive type stacked layer of the present invention are not limited to those discussed above. The material of the at least two second conductive type material layers with different refractive indexes in the second conductive type stacked layer can be selected from materials capable of limiting the color code of the transmission spectrum of the transparent solar cell module within a rectangular region formed of the chromaticity diagram of Commission International de l'Eclairage CIE (x,y), in which 0.45<x<0.55, and 0.4<y<0.5, or from materials capable of raising the color rendering index (Ra) of the transmission spectrum of the transparent solar cell module above 80, or from materials capable of raising the color temperature (CT) of the transmission spectrum of the transparent solar cell module above 2000 degrees Kelvin.

### Example

The solar cell module is fabricated, and the structure of the solar cell module is in sequence a glass substrate, a front transparent electrode, a p-type crystal silicon layer, an intrinsic microcrystalline silicon layer, an n-type stacked layer (an n-type silicon oxide (N—SiOₓ) layer/an n-type amorphous silicon (N-a-Si)), and a rear transparent electrode. The front transparent electrode is aluminium-doped lead oxide with an average thickness of 800 nm. An average thickness of the p-type crystal silicon layer is 10 nm. A thickness of the intrinsic microcrystalline silicon layer is 100 Å. An average thickness of the N—SiOₓ layer is 673.33 Å, its dark conductivity is 1.49×10⁻⁵ S/cm, and its refractive index is 2.3. An average thickness of the N-a-Si is 313.33 Å, its dark conductivity is 4.86×10⁴ S/cm, and its refractive index is 4. Then, the characteristics of a light ray are tested when the light ray enters via the glass substrate. A relationship between the light absorption quantum efficiency and wavelength is as shown in FIG. 2 by a curve 100.

### Comparison Example

A solar cell module is fabricated in a manner similar to the foregoing example and tested. However, the n-type stacked layer is replaced with a single layer of n-type amorphous silicon (N-a-Si). A relationship between the light absorption quantum efficiency and wavelength for the solar cell module is as shown in FIG. 2 by a curve 200.

As shown by a result in FIG. 2, for the transparent solar cell module fabricated with the single-layer N-a-Si being replaced by the n-type stacked layer of the present invention, the light absorption quantum efficiency (QE) of light at wavelengths of 500-800 nm is increased, so that a short-circuit current density Jsc of an device is raised from 5.45 mA/cm² to 6.04 mA/cm². In other words, the Jsc may be raised by 10.8%. Also, after calculation, for the transparent solar cell module fabricated with the single-layer N-a-Si being replaced by the n-type stacked layer of the present invention, the color rendering index (Ra) of the transmission spectrum is raised from 85 to 88.05, the color temperature (CT) of the transmission spectrum is raised from 1717 degrees Kelvin to 2321 degrees Kelvin, and the color code of the transmission spectrum is changed from CIE (0.57, 0.43) to CIE (0.5, 0.42).

In view of the above, the transparent solar cell module of the present invention may adjust the CIE, the Ra, and the CT of the transmission spectrum by using the n-type stacked layer, so as to improve a quality of transmitted light, achieving a more comfortable living space. Additionally, absorption of light at long wavelengths may be increased, and the short-circuit current density Jsc and the efficiency of a device can be increased, so as to achieve energy-saving. Moreover, the transparent solar cell module of the present invention may be applied to the BIPV for the integration to a building. On the other hand, the method of fabricating the transparent solar cell module of the present invention conforms to the current solar cell fabricating technology, and has a low fabrication cost.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A transparent solar cell module, comprising:
a transparent substrate;
a first transparent electrode on the transparent substrate;
a first conductive type layer on the first transparent electrode;
an intrinsic layer on the first conductive type layer;
a second conductive type stacked layer on the intrinsic layer, comprising at least two second conductive type material layers with different refractive indexes; and
a second transparent electrode on the second conductive type stacked layer.

2. The transparent solar cell module according to claim 1, wherein the first conductive type layer is a p-type layer and the second conductive type stacked layer is an n-type stacked layer.

3. The transparent solar cell module according to claim 2, wherein the n-type stacked layer comprises at least one n-type material layer with a low refractive index and at least one n-type material layer with a high refractive index, and a difference between the refractive index of the n-type material layer with the high refractive index and the refractive index of the n-type material layer with the low refractive index is greater than or equal to 1.

4. The transparent solar cell module according to claim 3, wherein the refractive index of the n-type material layer with the low refractive index is 2-2.5, and the refractive index of the n-type material layer with the high refractive index is 3-4.

5. The transparent solar cell module according to claim 3, wherein a material of the n-type material layer with the high refractive index comprises n-type amorphous silicon (N-a-Si) or n-type microcrystalline silicon (N-μc-Si), and a material of the n-type material layer with the low refractive index comprises n-type silicon oxide (N—SiOₓ), n-type silicon nitride (N—SiNₓ), or n-type silicon carbide (N—SiCₓ).

6. The transparent solar cell module according to claim 3, wherein the n-type material layer with the low refractive index is disposed between the intrinsic layer and the n-type material layer with the high refractive index, and the n-type material layer with the high refractive index is disposed between the n-type material layer with the low refractive index and the second transparent electrode.

7. The transparent solar cell module according to claim 2, wherein the p-type layer comprises p-type amorphous silicon, p-type microcrystalline silicon, p-type silicon carbide, or p-type silicon oxide.

8. The transparent solar cell module according to claim 1, wherein a material of the at least two second conductive type material layers with different refractive indexes is selected from materials capable of limiting the color code of a transmission spectrum of the transparent solar cell module within a rectangular region formed of a chromaticity diagram of Commission International de l'Eclairage CIE (x,y), in which 0.45<x<0.55, and 0.4<y<0.5.

9. The transparent solar cell module according to claim 1, wherein a material of the at least two second conductive type material layers with different refractive indexes is selected from materials capable of raising the color rendering index (Ra) of the transmission spectrum of the transparent solar cell module above 80.

10. The transparent solar cell module according to claim 1, wherein a material of the at least two second conductive type material layers with different refractive indexes is selected from materials capable of raising the color temperature (CT) of the transmission spectrum of the transparent solar cell module above 2000 degrees Kelvin.

11. The transparent solar cell module according to claim 1, wherein the first conductive type layer is an n-type layer and the second conductive type stacked layer is a p-type stacked layer.

12. The transparent solar cell module according to claim 11, wherein the p-type layer comprises p-type amorphous silicon, p-type microcrystalline silicon, p-type silicon carbide, or p-type silicon oxide.

13. The transparent solar cell module according to claim 1, wherein a material of the intrinsic layer comprises intrinsic amorphous silicon, intrinsic microcrystalline silicon, fluorine-doped intrinsic amorphous silicon, or fluorine-doped intrinsic microcrystalline silicon.

14. The transparent solar cell module according to claim 1, wherein a material of the first transparent electrode and a material of the second transparent electrode comprise transparent conductive oxide.

15. The transparent solar cell module according to claim 1, wherein the transparent substrate is a rigid substrate or a flexible substrate.

16. A method of fabricating a transparent solar cell module, comprising:
forming a first transparent electrode on a transparent substrate;
forming a first conductive type layer on the first transparent electrode;
forming an intrinsic layer on the first conductive type layer;
forming a second conductive type stacked layer on the intrinsic layer, wherein the second conductive type stacked layer comprises at least two second conductive type material layers with different refractive indexes; and
forming a second transparent electrode on the second conductive type stacked layer.

17. The method of fabricating a transparent solar cell module according to claim 16, wherein the first conductive type layer is a p-type layer and the second conductive type stacked layer is an n-type stacked layer.

18. The method of fabricating a transparent solar cell module according to claim 17, wherein the n-type stacked layer comprises at least one n-type material layer with a low refractive index and at least one n-type material layer with a high refractive index, and a difference between the refractive index of the n-type material layer with the high refractive index and the refractive index of the n-type material layer with the low refractive index is greater than or equal to 1.

19. The method of fabricating a transparent solar cell module according to claim 18, wherein the refractive index of the n-type material layer with the low refractive index is 2-2.5, and the refractive index of the n-type material layer with the high refractive refractive index is 3-4.

20. The method of fabricating a transparent solar cell module according to claim 17, wherein a material of the n-type material layer with the high refractive index comprises n-type amorphous silicon (N-a-Si) or n-type microcrystalline silicon (N-μc-Si), and a material of the n-type material layer with the low refractive index comprises n-type silicon oxide (N—SiOₓ), n-type silicon nitride (N—SiNₓ), or n-type silicon carbide (N—SiCₓ).

21. The method of fabricating a transparent solar cell module according to claim 17, wherein the method of forming the n-type stacked layer comprises:
forming the n-type material layer with the low refractive index on the intrinsic layer; and
forming the n-type material layer with the high refractive index on the n-type material layer with the low refractive index.

22. The method of fabricating a transparent solar cell module according to claim 16, wherein a material of the at least two second conductive type material layers with different refractive indexes is selected from materials capable of limiting a color code (CIE) of a transmission spectrum of the transparent solar cell module within a rectangular region formed of a chromaticity diagram of Commission International de l'Eclairage CIE (x,y), in which 0.45<x<0.55, and 0.4<y<0.5.

23. The method of fabricating a transparent solar cell module according to claim 16, wherein a material of the at least two second conductive type material layers with different refractive indexes is selected from materials capable of raising a color rendering index (Ra) of the transmission spectrum of the transparent solar cell module above 80.

24. The method of fabricating a transparent solar cell module according to claim 16, wherein a material of the at least two second conductive type material layers with different refractive indexes is selected from materials capable of raising a color temperature (CT) of the transmission spectrum of the transparent solar cell module above 2000 degrees Kelvin.

25. The method of fabricating a transparent solar cell module according to claim 16, wherein the first conductive type layer is an n-type layer and the second conductive type stacked layer is a p-type stacked layer.
